(19) United States
(12) Patent Application Publication
(10) Pub. No.: US 2023/0409268 A1
(43) Pub. Date: Dec. 21, 2023

(54) DISPLAY DEVICE AND OPERATING ENVIRONMENT INFORMATION PROVIDING SYSTEM OF MOBILE MEANS INCLUDING THE SAME

(71) Applicant: Samsung Display Co., LTD., Yongin-si (KR)

(72) Inventors: Hae Yun CHOI, Yongin-si (KR); Byeong Hwa CHOI, Yongin-si (KR)

(21) Appl. No.: 18/334,060

(22) Filed: Jun. 13, 2023

(30) Foreign Application Priority Data
Jun. 17, 2022 (KR) 10-2022-0074331

(51) Int. Cl. G06F 3/14; H01L 25/16; G06F 3/147; H04N 23/90; B62J 50/22

(52) U.S. Cl. CPC G06F 3/1423; H01L 25/167; G06F 3/147; H04N 23/90; B62J 50/22

(57) ABSTRACT

The present disclosure relates to a display device and an operating-environment-information-providing system of a mobile means comprising the same. In one or more embodiments, a display device includes multiprocessors respectively at different locations in a mobile means, configured to capture images in different directions, and configured to sense distances to proximate objects, a main display panel on an instrument board of the mobile means, and configured to display at least one of image including an image captured by the multiprocessors, a surrounding-environment-information image, a driving-environment-information image, an instrument-information image, a driving-information image, or a safety-state-information image, and a main processor configured to control an image display operation of the main display panel so that the at least one image is displayed on the main display panel.

### CROSS-REFERENCE TO RELATED APPLICATION

This application claims priority to, and the benefit of, Korean Patent Application No. 10-2022-0074331 filed on Jun. 17, 2022 in the Korean Intellectual Property Office, the contents of which in its entirety are herein incorporated by reference.

### BACKGROUND

### 1. Field

The present disclosure relates to a display device, and to an operating-environment-information-providing system of a mobile means including the same.

### 2. Description of the Related Art

As the information society develops, the demand for display devices for displaying images has increased and diversified. The display devices may be flat panel display devices, such as liquid crystal displays (LCDs), field emission displays (FEDs), or light-emitting displays (LEDs).

Light-emitting display devices may be organic light-emitting display devices including organic light-emitting diode elements as light-emitting elements, inorganic light-emitting display device including inorganic semiconductor elements as light-emitting elements, or light-emitting diode display devices including micro light-emitting diode elements as light-emitting elements.

Recently, a method of applying the light-emitting diode display devices to head mounted displays, head-up displays, instrument devices of vehicles and two-wheeled vehicles, and the like, by expanding the usability of the light-emitting diode display devices has been demanded.

### SUMMARY

Aspects of the present disclosure provide a display device capable of displaying, in real time, instrument information, driving information, safety state information, and the like, of a mobile means in conjunction with electronic devices, such as a camera and a sensor, and an operating-environment-information-providing system of a mobile means (e.g., a system for providing information regarding an operating environment of a vehicle) including the same.

Aspects of the present disclosure also provide a display device capable of displaying instrument information, safety state information, and the like, on an instrument board, a windscreen, and the like, of a mobile means using a micro-light-emitting diode (LED) display device, and an operating-environment-information-providing system of a mobile means including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, a display device includes multiprocessors respectively at different locations in a mobile means, configured to capture images in different directions, and configured to sense distances to proximate objects, a main display panel on an instrument board of the mobile means, and configured to display at least one of image including an image captured by the multiprocessors, a surrounding-environment-information image, a driving-environment-information image, an instrument-information image, a driving-information image, or a safety-state-information image, and a main processor configured to control an image display operation of the main display panel so that the at least one image is displayed on the main display panel.

The display device may further include at least one sub-display panel for displaying at least one second image that is different from the at least one image displayed on the main display panel, and at least one screen display module for emitting at least one of the image captured by the multiprocessors, the surrounding-environment-information image, the driving-environment-information image, the instrument-information image, the driving-information image, and the safety-state-information image to a windscreen, to a mirror, or to a surface of any one cover of the mobile means.

The main processor may be configured to control an image display operation of each of the at least one sub-display panel and the at least one screen display module so that the at least one image is displayed on the at least one sub-display panel and the at least one screen display module.

At least one of the main display panel and the sub-display panel may include a partition wall partitioned and in an RGBG matrix structure on a substrate, light-emitting elements respectively in emission areas arranged in the RGBG matrix structure by partition of the partition wall, and extending in a thickness direction of the substrate, base resins in the emission areas including the light-emitting elements, and optical patterns selectively on at least one of the emission areas.

First to third emission areas or first to fourth emission areas of the emission areas may be in the RGBG matrix structure in each pixel area, wherein the first emission area includes a first light-emitting element for emitting first light of a wavelength band implementing any one of red, green, and blue, wherein the second emission area includes a second light-emitting element for emitting second light of a wavelength band implementing any one color that is different from that of the first light among red, green, and blue, wherein the third emission area includes a third light-emitting element for emitting third light of a wavelength band implementing any one color that is different from those of the first light and the second light among red, green, and blue, and wherein the fourth emission area includes a fourth light-emitting element for emitting fourth light of the same wavelength band as any one of the first light to the third light.

Sizes or planar areas of the first to fourth emission areas may be the same as each other, wherein a distance between the first and second emission areas neighboring to each other in a horizontal direction or a diagonal direction, a distance between the second and third emission areas neighboring to each other in the horizontal direction or the diagonal direction, a distance between the first and third emission areas neighboring to each other in the horizontal direction or the diagonal direction, and a distance between the third and fourth emission areas neighboring to each other in the horizontal direction or the diagonal direction, are the same as each other.

The multiprocessors may be respectively at different locations of the mobile means, configured to capture the images in different respective directions, configured to sense respective distances to a proximate object in the different respective directions, and configured to display and emit images from the main processor under the control of the main processor.

The multiprocessors may be respectively in any one of a front direction, a rear direction, a side direction, and a diagonal direction with respect to the mobile means.

First to third multiprocessors of the multiprocessors may be on surfaces of a left rearview mirror in the front direction, the side direction, and the rear direction, respectively, configured to capture images in at least one of a front left direction, a left side direction, the rear direction, and a left diagonal direction of the mobile means, and configured to sense distances to a proximate object, wherein fourth to sixth multiprocessors of the multiprocessors are on surfaces of a right rearview mirror in the front direction, the side direction, and the rear direction, respectively, configured to capture images in at least one of a front right direction, a right side direction, the rear direction, and a right diagonal direction of the mobile means, and configured to sense distances to the proximate object.

The multiprocessors may be at different respective locations of at least one of a top cowling cover, a bottom cowling cover, a front grille, a side grille, a front cover, a side cover, a taillight cover, and one or more rearview mirrors of the mobile means.

A first multiprocessor of the multiprocessors may be in a front direction of the mobile means on a first rearview mirror of the one or more rearview mirrors or the front cover of the mobile means, wherein a second multiprocessor is in one side direction of the mobile means on a second rearview mirror of the one or more rearview mirrors or the top cowling cover of the mobile means, wherein a third multiprocessor is in the other side direction of the mobile means on a third rearview mirror of the one or more rearview mirrors or the top cowling cover of the mobile means, wherein a fourth multiprocessor is in one side diagonal direction of the mobile means on a fourth rearview mirror of the one or more rearview mirrors or one side cover of the mobile means, wherein a fifth multiprocessor is in the other side diagonal direction of the mobile means on a fifth rearview mirror of the one or more rearview mirrors or the other side cover of the mobile means, and wherein a sixth multiprocessor is in a rear direction of the mobile means on a sixth rearview mirror of the one or more rearview mirrors or a taillight direction cover of the mobile means.

First to sixth multiprocessors of the multiprocessors may be at six respective locations of the mobile means, configured to capture images in six respective surface directions, may be configured to sense distances to proximate objects in the six respective surface directions, and may be configured display images from the main processor in six respective surface directions under the control of the main processor.

The first multiprocessor may include a first camera module, a first sensing module, and a first display module, wherein the second multiprocessor includes a second camera module, a second sensing module, and a second display module, wherein the third multiprocessor includes a third camera module, a third sensing module, and a third display module, wherein the fourth multiprocessor includes a fourth camera module, a fourth sensing module, and a fourth display module, wherein the fifth multiprocessor includes a fifth camera module, a fifth sensing module, and a fifth display module, and wherein the sixth multiprocessor includes a sixth camera module, a sixth sensing module, and a sixth display module.

The first to sixth display modules may include a display panel, at least one diffusion lens, and at least one focus forming lens, wherein the display panel includes a partition wall partitioned and in an RGBG matrix structure on a substrate, light-emitting elements each in emission areas arranged in the RGBG matrix structure by partition of the partition wall, and extending in a thickness direction of the substrate, base resins in the emission areas including the light-emitting elements, and optical patterns selectively on at least one of the emission areas.

The first to third camera modules, the first to third sensing modules, and the first to third display modules may be respectively on surfaces of a left rearview mirror in a front direction, a side direction, and a rear direction, wherein the fourth to sixth camera modules, the fourth to sixth sensing modules, and the fourth to sixth display modules are respectively on surfaces of a right rearview mirror in the front direction, the side direction, and the rear direction.

The first to sixth camera modules, the first to sixth sensing modules, and the first to sixth display modules may be respectively in different directions on at least one of a top cowling cover, a bottom cowling cover, a front or side grille, front and side covers, a taillight cover, and one or more rearview mirrors of the mobile means.

The first camera module, the first sensing module, and the first display module may be in a front direction of the mobile means on a rearview mirror or a front cover of the mobile means, wherein the second camera module, the second sensing module, and the second display module are in one side direction of the mobile means on the rearview mirror or a top cowling cover of the mobile means, wherein the third camera module, the third sensing module, and the third display module are in the other side direction of the mobile means on the rearview mirror or the top cowling cover of the mobile means, wherein the fourth camera module, the fourth sensing module, and the fourth display module are in one side diagonal direction of the mobile means on the rearview mirror or one side cover of the mobile means, wherein the fifth camera module, the fifth sensing module, and the fifth display module are in the other side diagonal direction of the mobile means on the rearview mirror or the other side cover of the mobile means, and wherein the sixth camera module, the sixth sensing module, and the sixth display module are in a rear direction of the mobile means on the rearview mirror or a taillight direction cover of the mobile means.

According to one or more embodiments of the present disclosure, an operating-environment-information-providing system of a two-wheeled mobile device includes a display device assembled to, or formed integrally with, the two-wheeled mobile device, and configured to display a driving-environment-information image, an instrument-information image, and a driving-information image of the two-wheeled mobile device, wherein the display device includes multiprocessors respectively in different directions in the two-wheeled mobile device for capturing images in the different directions, and for sensing distances to proximate objects, a main display panel for displaying at least one of at least one image captured by the multiprocessors, a surrounding-environment-information image, and a safety-state-information image, and a main processor for controlling an image display operation of the main display panel so that the at least one image is displayed on the main display panel.

The main processor may be configured to control an image display operation of each of at least one sub-display panel and at least one screen display module so that the at least one image is displayed on the at least one sub-display panel and the at least one screen display module.

The two-wheeled mobile device may include an electric bicycle, a personal mobile device, a two-wheeled motor device, a two-wheeled parallel vehicle, a motorcycle, or logistics and construction machinery.

A display device according to one or more embodiments of the present disclosure displays driving information and safety state information of a mobile means in real time in conjunction with various electronic devices, such as cameras and sensors, such that the usability of the display devices may be increased.

In addition, the display device according to one or more embodiments of the present disclosure displays various information images on an instrument board, a windscreen, and the like, of the mobile means using a micro-LED display device, and thus, may further improve a display quality of an information display image.

The aspects of the present disclosure are not limited to the aforementioned aspects, and various other aspects are included in the present specification.

### BRIEF DESCRIPTION OF THE DRAWINGS

The above and other aspects of the present disclosure will become more apparent by describing in detail embodiments thereof with reference to the attached drawings, in which:

FIG. 1 is a plan view illustrating an example in which a display device according to one or more embodiments of the present disclosure is applied to a two-wheeled mobile device;

FIG. 2 is a side view illustrating an example in which the display device according to one or more embodiments is applied to the two-wheeled mobile device;

FIG. 3 is a front view illustrating an example in which the display device according to one or more embodiments is applied to the two-wheeled mobile device;

FIG. 4 is a schematic block diagram illustrating components of the display device illustrated in FIGS. 1 to 3;

FIG. 5 is an illustrative view illustrating image capturing directions of first to sixth camera modules illustrated in FIGS. 1 to 4;

FIG. 6 is a view illustrating an arrangement structure of a main display panel, a sub-display panel, and a screen display module according to one or more embodiments;

FIG. 7 is a layout diagram illustrating the main display panel illustrated in FIGS. 4 and 6;

FIG. 8 is a layout diagram illustrating area A of FIG. 7 in detail;

FIG. 9 is a layout diagram illustrating, in detail, pixels illustrated in area B of FIG. 8;

FIG. 10 is a cross-sectional view illustrating an example of the main display panel taken along the line I-I′ of FIG. 9;

FIG. 11 is an enlarged cross-sectional view illustrating an example of a light-emitting element of FIG. 10 in detail;

FIG. 12 is a schematic view illustrating a configuration of any one display module illustrated in FIG. 4;

FIG. 13 is a view illustrating an image display method of the main display panel, the sub-display panel, and the screen display module according to one or more embodiments;

FIG. 14 is an illustrative view illustrating display image emission directions of first to sixth display panels illustrated in FIGS. 1 to 4;

FIG. 15 is a perspective view illustrating an example in which the display device of the present disclosure is applied to a personal mobile device according to one or more other embodiments;

FIG. 16 is another perspective view illustrating an example in which the display device of the present disclosure is applied to another personal mobile device;

FIG. 17 is an illustrative view illustrating an instrument board and a center fascia of a vehicle including a display module according to one or more embodiments;

FIG. 18 is an illustrative view illustrating an eyeglasses-type virtual reality device including the display module according to one or more embodiments;

FIG. 19 is an illustrative view illustrating a watch-type smart device including the display module according to one or more embodiments; and

FIG. 20 is an illustrative view illustrating a transparent display device including the display module according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

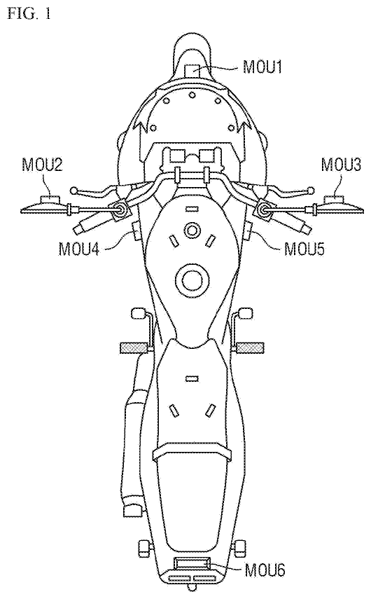

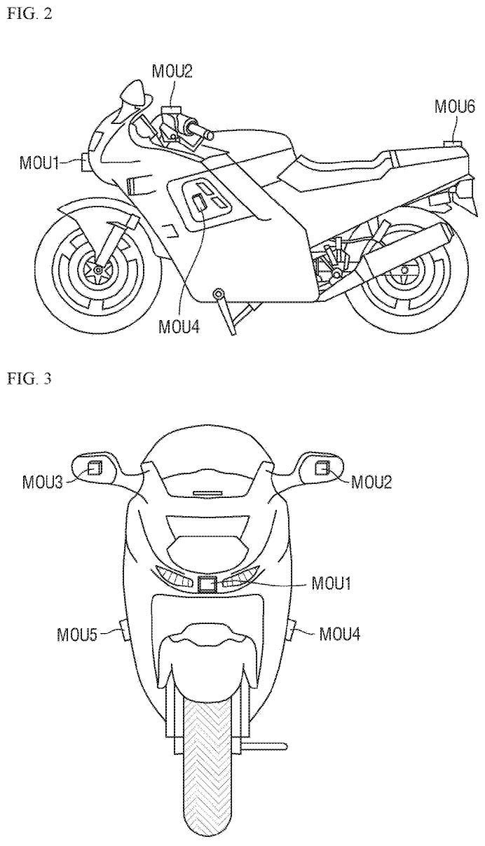

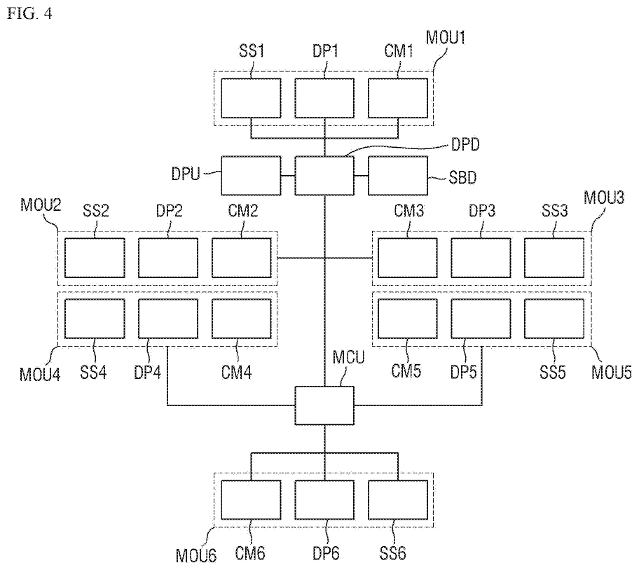

FIG. 1 is a plan view illustrating an example in which a display device according to one or more embodiments of the present disclosure is applied to a two-wheeled mobile device. In addition, FIG. 2 is a side view illustrating an example in which the display device according to one or more embodiments is applied to the two-wheeled mobile device, and FIG. 3 is a front view illustrating an example in which the display device according to one or more embodiments is applied to the two-wheeled mobile device.

Referring to FIGS. 1 to 3, a display device, and an operating-environment-information-providing system (e.g., a system for providing information regarding an operating environment) including the display device, may be mounted in or formed integrally with various mobile means, such as two-wheeled mobile devices, for example, electric bicycles, personal mobile devices, two-wheeled motor devices, two-wheeled parallel vehicles, and motorcycles, four-wheeled vehicles, logistics and construction machinery. Hereinafter will be described an example in which the operating-environment-information-providing system is formed integrally with the two-wheeled mobile device.

The display device of the operating-environment-information-providing system may display surrounding environment information, driving environment information, instrument information, driving information, safety state information, and the like, regarding the two-wheeled mobile device on an instrument board, a windscreen, and the like, in conjunction with electric devices, such as a sensing module, a camera module, and a main board of the two-wheeled mobile device. To this end, the display device of the operating-environment-information-providing system may include a plurality of multiprocessors (e.g., multiprocessing units), for example, first to sixth multiprocessors MOU1 to MOU6, including a sensing module and a camera module. The respective multiprocessors MOU1 to MOU6 may be located respectively in different directions on the basis of the mobile means, may capture images in the different directions, and may sense distances to one or more proximate objects (e.g., proximity objects). In addition, the respective multiprocessors MOU1 to MOU6 may display and emit images from a main processor in respective different directions under the control of the main processor.

As an example, the multiprocessors MOU1 to MOU6 of the display device may be located respectively in at least one of a front direction, a rear direction, a side direction, and a diagonal direction on surfaces of one or more rearview mirrors formed in the mobile means. In this case, the respective multiprocessors MOU1 to MOU6 may be located in the respective different directions on the basis of the mobile means. Accordingly, the respective multiprocessors MOU1 to MOU6 may capture images in at least one of the front direction, the rear direction, the side direction, and the diagonal direction of one or more rearview mirrors, and may sense distances to proximate objects. In addition, the respective multiprocessors MOU1 to MOU6 may display and emit images from the main processor in the respective different directions under the control of the main processor.

For example, in one or more other embodiments, the first to third multiprocessors MOU1 to MOU3 may be located on surfaces of a left rearview mirror in the front direction, the side direction, and the rear direction, respectively, may capture images in at least one of the front direction, the side direction, the rear direction, and the diagonal direction of the mobile means, and may sense distances to proximate objects. At the same time, the first to third multiprocessors MOU1 to MOU3 may display and emit images in the respective different directions. Also, the fourth to sixth multiprocessors MOU4 to MOU6 may be located on surfaces of a right rearview mirror in the front direction, the side direction, and the rear direction, respectively, may capture images in at least one of the front direction, the rear direction, the side direction, and the diagonal direction of the mobile means, and may sense distances to proximate objects. At the same time, the fourth to sixth multiprocessors MOU4 to MOU6 may display and emit images in the respective different directions.

As another example of one or more other embodiments, the multiprocessors MOU1 to MOU6 of the display device may be located respectively in different directions on at least one of a top cowling cover, a bottom cowling cover, a front or side grille, front and side covers, and a taillight cover, as well as on one or more rearview mirrors of the mobile means. Accordingly, the respective multiprocessors MOU1 to MOU6 may capture images in at least one of the front direction, the side direction, the rear direction, and the diagonal direction of the mobile means, and may sense distances to proximate objects.

For example, referring to FIG. 1, the first multiprocessor MOU1 of the multiprocessors MOU1 to MOU6 may be located in the front direction of the mobile means on a rearview mirror or a front cover of the mobile means, may capture an image in the front direction of the mobile means, and may sense distances to proximate objects in the front direction. In addition, the first multiprocessor MOU1 may display and emit a driving-information image (e.g., an image depicting driving information) or a position-information image (e.g., an image depicting position information) in the front direction under the control of the main processor.

In addition, the second multiprocessor MOU2 of the multiprocessors MOU1 to MOU6 may be located in one side direction of the mobile means on one rearview mirror or the top cowling cover of the mobile means, may capture an image in one side direction or one side diagonal direction of the mobile means, and may sense distances to proximate objects. In addition, the second multiprocessor MOU2 may display and emit a driving information or position-information image in one side direction or one side diagonal direction of the mobile means.

The third multiprocessor MOU3 may be located in the other side direction of the mobile means on the other rearview mirror or the top cowling cover of the mobile means, may capture an image in the other side direction or the other side diagonal direction of the mobile means and may sense distances to proximate objects. In addition, the third multiprocessor MOU3 may display and emit a driving information or position-information image in the other side direction or the other side diagonal direction of the mobile means.

The fourth multiprocessor MOU4 may be located in one side diagonal direction of the mobile means on or adjacent the one rearview mirror or one side cover of the mobile means, may capture an image in one side diagonal direction of the mobile means and may sense distances to proximate objects. In addition, the fourth multiprocessor MOU4 may display and emit a driving information or position-information image in one side diagonal direction of the mobile means.

The fifth multiprocessor MOU5 may be located in the other side diagonal direction of the mobile means on or adjacent the other rearview mirror or the other side cover of the mobile means, may capture an image in the other side diagonal direction of the mobile means and may sense distances to proximate objects. In addition, the fifth multiprocessor MOU5 may display and emit a driving information or position-information image in the other side diagonal direction of the mobile means.

The sixth multiprocessor MOU6 may be located in the rear direction of the mobile means on the rearview mirror or a taillight direction cover of the mobile means, may capture an image in the rear direction of the mobile means and may sense distances to proximate objects. In addition, the sixth multiprocessor MOU6 may display and emit a driving information or position-information image in the rear direction of the mobile means.

FIG. 4 is a schematic block diagram illustrating components of the display device illustrated in FIGS. 1 to 3.

Referring to FIGS. 1 to 4, the display device of the operating-environment-information-providing system includes the plurality of multiprocessors MOU1 to MOU6, a main display panel DPD, at least one sub-display panel SBD, at least one screen display module DPU, and a main processor MCU.

The plurality of multiprocessors MOU1 to MOU6 may be divided into at least four multiprocessors so as to capture images in at least four directions on the basis of the mobile means and may sense distances to proximate objects. For example, the display device may include first to sixth multiprocessors MOU1 to MOU6.

The first to sixth multiprocessors MOU1 to MOU6 may be located in different directions in the mobile means, may capture images in six different surface directions, and may sense distances to proximate objects. In addition, the respective multiprocessors MOU1 to MOU6 may display and emit images from the main processor in different six surface directions under the control of the main processor.

Each of the multiprocessors MOU1 to MOU6 may include each camera module, sensing module, and display module.

For example, the first multiprocessor MOU1 may include a first camera module CM1, a first sensing module SS1, and a first display module DP1, and the second multiprocessor MOU2 may include a second camera module CM2, a second sensing module SS2, and a second display module DP2.

The third multiprocessor MOU3 may include a third camera module CM3, a third sensing module SS3, and a third display module DP3, and the fourth multiprocessor MOU4 may include a fourth camera module CM4, a fourth sensing module SS4, and a fourth display module DP4.

The fifth multiprocessor MOU5 may include a fifth camera module CM5, a fifth sensing module SS5, and a fifth display module DP5, and the sixth multiprocessor MOU6 may include a sixth camera module CM6, a sixth sensing module SS6, and a sixth display module DP6.

The first to sixth camera modules CM1 to CM6 of the display device may be located respectively in at least one of the front direction, the rear direction, the side direction, and the diagonal direction on the surfaces of one or more rearview mirrors formed in the mobile means. For example, the first to sixth camera modules CM1 to CM6 may be located in the respective different directions on the basis of the mobile means. Accordingly, each of the camera modules CM1 to CM6 may capture an image in at least one of the front direction, the rear direction, the side direction, and the diagonal direction on one or more rearview mirrors, and may transmit captured image data to the main processor MCU.

As an example, the first to third camera modules CM1 to CM3 of the first to sixth camera modules CM1 to CM6 may be located on surfaces of the left rearview mirror in the front direction, the side direction, and the rear direction, respectively, and may capture images in at least one of the front direction, the side direction, the rear direction, and the diagonal direction of the mobile means.

Further, the fourth to sixth camera modules CM4 to CM6 of the first to sixth camera modules CM1 to CM6 may be located on surfaces of the right rearview mirror in the front direction, the side direction, and the rear direction, respectively, and may capture images in at least one of the front direction, the rear direction, the side direction, and the diagonal direction of the mobile means.

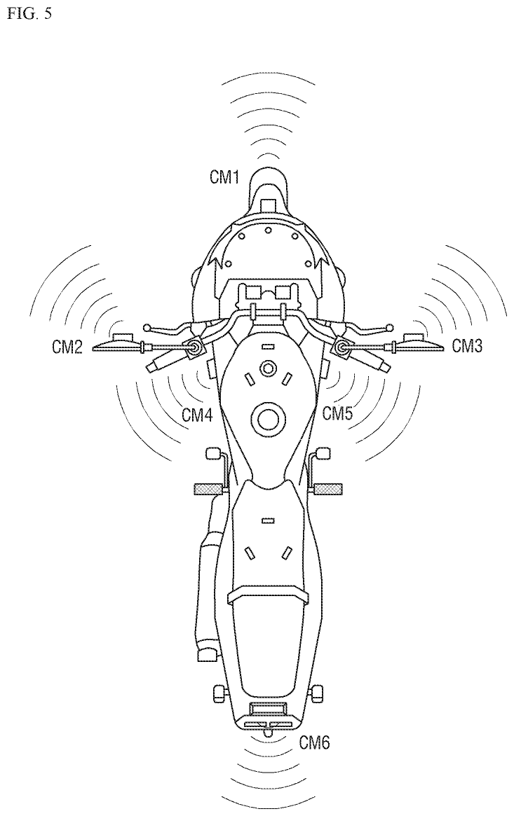

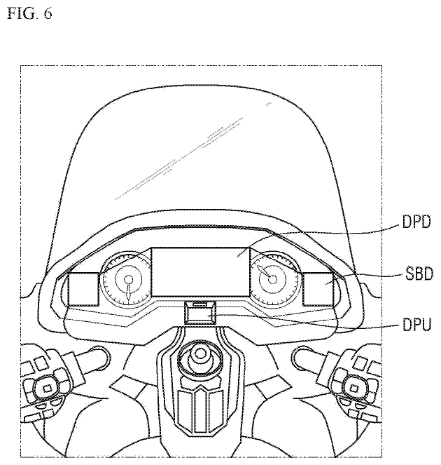

FIG. 5 is an illustrative view illustrating image capturing directions of first to sixth camera modules illustrated in FIGS. 1 to 4.

Referring to FIG. 5, the first to sixth camera modules CM1 to CM6 may be located respectively in different directions on at least one of the top cowling cover, the bottom cowling cover, the front or side grille, the front and side covers, and the taillight cover, as well as on one or more rearview mirrors of the mobile means. Accordingly, each of the camera modules CM1 to CM6 may capture an image in at least one of the front direction, the side direction, the rear direction, and the diagonal direction of the mobile means.

For example, the first camera module CM1 of the first to sixth camera modules CM1 to CM6 may be located in the front direction of the mobile means on the rearview mirror or the front cover of the mobile means, and may capture an image in the front direction of the mobile means. In addition, the second camera module CM2 may be located in one side direction of the mobile means on one rearview mirror or the top cowling cover of the mobile means, and may capture an image in one side direction or one side diagonal direction of the mobile means.

In addition, the third camera module CM3 of the first to sixth camera modules CM1 to CM6 may be located in the other side direction of the mobile means on the other rearview mirror or the top cowling cover of the mobile means, and may capture an image in the other side direction or the other side diagonal direction of the mobile means. The fourth camera module CM4 may be located in one side diagonal direction of the mobile means on or adjacent to the one rearview mirror or one side cover of the mobile means, and may capture an image in one side diagonal direction of the mobile means.

In addition, the fifth camera module CM5 may be located in the other side diagonal direction of the mobile means on or adjacent to the other rearview mirror or the other side cover of the mobile means, and may capture an image in the other side diagonal direction of the mobile means. In addition, the sixth camera module CM6 may be located in the rear direction of the mobile means on the rearview mirror or the taillight cover of the mobile means, and may capture an image in the rear direction of the mobile means.

The first to sixth sensing modules SS1 to SS6 of the display device may be located at the same positions as the first to sixth camera modules CM1 to CM6 and in the same directions as the first to sixth camera modules CM1 to CM6 in parallel with the first to sixth camera modules CM1 to CM6, respectively. Accordingly, the first to sixth sensing modules SS1 to SS6 may sense distances to proximate objects in the respective directions that are the same as image capturing directions of the first to sixth camera modules CM1 to CM6.

For example, the first to sixth sensing modules SS1 to SS6 may be located respectively in at least one of the front direction, the rear direction, the side direction, and the diagonal direction on the surfaces of one or more rearview mirrors formed in the mobile means, similar to the first to sixth camera modules CM1 to CM6. Accordingly, the first to sixth sensing modules SS1 to SS6 may be located in the respective different directions on the basis of the mobile means. In addition, the first to sixth sensing modules SS1 to SS6 may sense distances to proximate objects in at least one of the front direction, the rear direction, the side direction, and the diagonal direction of one or more rearview mirrors.

Alternatively, the first to sixth sensing modules SS1 to SS6 may be located respectively in different directions on at least one of the top cowling cover, the bottom cowling cover, the front and side grille, the front and side covers, and the taillight cover, as well as on one or more rearview mirrors of the mobile means, similar to the first to sixth camera modules CM1 to CM6. Accordingly, a description of arrangement positions and arrangement directions of the first to sixth sensing modules SS1 to SS6 will be replaced with the description of the arrangement positions and the arrangement directions of the first to sixth camera modules CM1 to CM6.

The first to sixth display modules DP1 to DP6 of the display device may be located at the same positions as the first to sixth camera modules CM1 to CM6 and the first to sixth sensing modules SS1 to SS6 and in the same directions as the first to sixth camera modules CM1 to CM6 and the first to sixth sensing modules SS1 to SS6 in parallel with the first to sixth camera modules CM1 to CM6 and the first to sixth sensing modules SS1 to SS6, respectively. Accordingly, the first to sixth display modules DP1 to DP6 may display and emit driving information or position-information images in the same directions as the image capturing directions of the first to sixth camera modules CM1 to CM6. Hereinafter, image display structures, image display directions, image emission structure, and the like, of the first to sixth display modules DP1 to DP6 will be described in more detail with reference to the accompanying drawings.

FIG. 6 is a view illustrating an arrangement structure of a main display panel, a sub-display panel, and a screen display module according to one or more embodiments.

Referring to FIG. 6, the main display panel DPD may be located in a front direction of a driver's seat, such as at an instrument board or a dashboard of the mobile means. The main display panel DPD receives driving control signals and image data from the main processor MCU. In addition, the main display panel DPD displays at least one of at least one image captured by each of the multiprocessors MOU1 to MOU6, a surrounding-environment-information image (e.g., an image depicting information regarding the surrounding environment), a driving-environment-information image (e.g., an image depicting information regarding the driving environment), an instrument-information image (e.g., an image depicting instrument information), a driving-information image, and a safety-state-information image (e.g., an image depicting information regarding a safety state) under the control of the main processor MCU.

At least one sub-display panel SBD may be located in the front direction of the driver's seat, such as at the instrument board or the dashboard of the mobile means, separately from the main display panel DPD. The sub-display panel SBD receives driving control signals and image data from the main processor MCU. The sub-display panel SBD may display at least one of at least one image captured by each of the multiprocessors MOU1 to MOU6, the surrounding-environment-information image, the driving-environment-information image, the instrument-information image, the driving-information image, and the safety-state-information image under the control of the main processor MCU. In this case, the sub-display panel SBD may display an image different from the image displayed on the main display panel DPD under the control of the main processor MCU.

At least one screen display module DPU may be located in the front direction of the driver's seat, such as the instrument board, the dashboard, or the top cowling cover of the mobile means, separately from the main display panel DPD. The screen display module DPU receives driving control signals and image data from the main processor MCU. The screen display module DPU emits an image so that the image is displayed through the windscreen, the mirror, a surface of any one cover, or the like, of the mobile means under the control of the main processor MCU. In this case, the screen display module DPU may emit at least one of at least one image captured by each of the multiprocessors MOU1 to MOUE, the surrounding-environment-information image, the driving-environment-information image, the instrument-information image, the driving-information image, and the safety-state-information image. For example, the windscreen or the mirror may include a transparent lens, a translucent optical waveguide (e.g., a prism), or the like. Accordingly, at least one image displayed through the screen display module DPU may be recognized by driver's eyes through the optical waveguide, the transparent lens, or the like of the windscreen or the mirror in the front direction.

The main processor MCU controls an image display operation of each of the main display panel DPD, at least one sub-display panel SBD, and the screen display module DPU so that at least one image is displayed on the main display panel DPD, the sub-display panel SBD, and the screen display module DPU.

The main processor MCU receives image data and distance sensing signals in at least one of the front direction, both side directions, the diagonal direction, and the rear direction of the mobile means in real time. In addition, the main processor MCU detects surrounding information including real-time driving information of the vehicle, distance information between the vehicle and surrounding objects, and the like. In addition, the main processor MCU receives control information of the mobile means/two-wheeled mobile device. The main processor MCU classifies real-time driving information, control information, and driving environment information of the mobile means according to display positions of the first to sixth display modules DP1 to DP6, and generates driving environment image data to be displayed separately for each of the first to sixth display modules DP1 to DP6. In addition, the main processor MCU controls the first to sixth display modules DP1 to DP6, the main display panel DPD, the sub-display panel SBD, and the screen display module DPU so that different driving environment images are displayed through the first to sixth display modules DP1 to DP6, the main display panel DPD, the sub-display panel SBD, and the screen display module DPU, respectively.

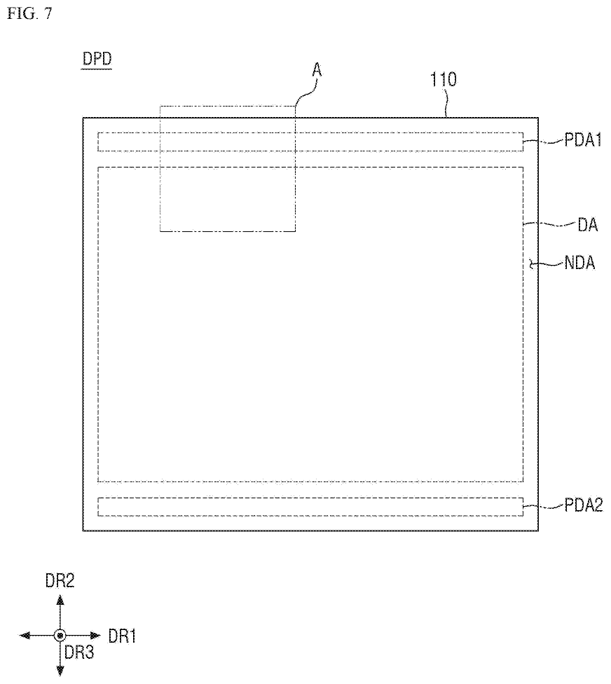

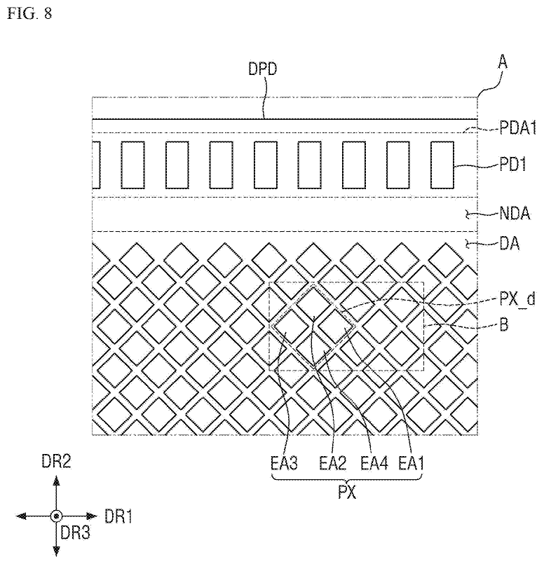

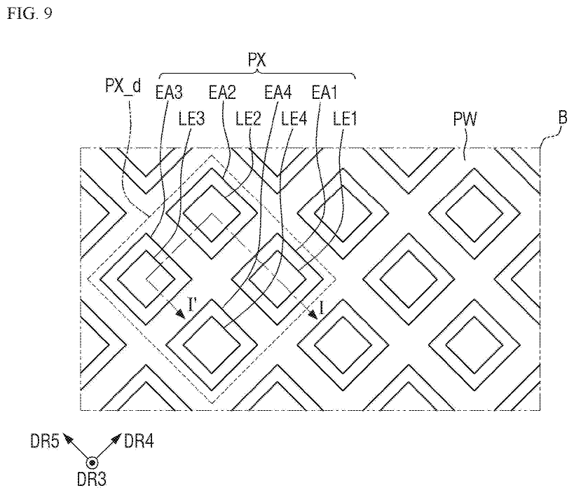

FIG. 7 is a layout diagram illustrating the main display panel illustrated in FIGS. 4 and 6. In addition, FIG. 8 is a layout diagram illustrating area A of FIG. 7 in detail, and FIG. 9 is a layout diagram illustrating, in detail, pixels illustrated in area B of FIG. 8.

The main display panel DPD of FIGS. 7 to 9 or the sub-display panel SBD may be formed in a light-emitting-diode-on-silicon (LEDoS) structure in which light-emitting diode elements are located on a semiconductor circuit substrate formed by a semiconductor process. In other words, it will be mainly described that the main display panel DPD or the sub-display panel SBD is a micro or nano light-emitting diode display panel (micro or nano light-emitting diode display module) including micro or nano light-emitting diodes as light-emitting elements. The sub-display panel SBD and the main display panel DPD have the substantially same layout, structure and components.

In FIGS. 7 to 9, a first direction DR1 refers to a transverse direction of the main display panel DPD, a second direction DR2 refers to a longitudinal direction of the main display panel DPD, and a third direction DR3 refers to a thickness direction of the main display panel DPD or a thickness direction of the semiconductor circuit substrate. In addition, a fourth direction DR4 refers to a diagonal direction of the main display panel DPD, and the fifth direction DR5 refers to a diagonal direction crossing the fourth direction DR4. In this case, “left,” “right,” “upper,” and “lower” refer to directions when the main display device PDP is viewed in plan view. For example, “right side” refers to one side in the first direction DR1, “left side” refers to the other side in the first direction DR1, “upper side” refers to one side in the second direction DR2, and “lower side” refers to the other side in the second direction DR2. In addition, “upper portion” refers to one side in the third direction DR3, and “lower portion” refers to the other side in the third direction DR3.

Referring to FIGS. 7 to 9, the main display panel DPD includes a display area DA and a non-display area NDA.

The main display panel DPD may have a rectangular shape, in plan view, having long sides in the first direction DR1 and short sides in the second direction DR2. However, the shape of the main display panel DPD in plan view is not limited thereto, and the main display panel DPD may have polygonal shapes other than the rectangular shape, a circular shape, an elliptical shape, or an irregular shape in plan view.

The display area DA may be an area in which an image is displayed, and the non-display area NDA may be an area in which an image is not displayed. A shape of the display area DA in plan view may follow the shape of the main display panel DPD in plan view. It is illustrated in FIG. 7 that the shape of the display area DA in plan view is a rectangular shape. The display area DA may be located in a central area of the main display panel DPD. The non-display area NDA may be located around the display area DA. The non-display area NDA may be located to surround the display area DA.

A first pad part PDA1 may be located in the non-display area NDA. The first pad part PDA1 may be located on the upper side of the main display panel DPD. The first pad part PDA1 may include first pads PD1 connected to an external circuit board. Meanwhile, a second pad part PDA2 may be located in the non-display area NDA. The second pad part PDA2 may be located on the lower side of the main display panel DPD. The second pad part PDA2 may include second pads to be connected to the external circuit board. Such second pad part PDA2 may be omitted.

The display area DA of the main display panel DPD may include a plurality of pixels PX. Each pixel PX may be defined as a minimum light-emitting unit capable of displaying white light in each defined pixel area PX_d.

The pixels PX located as minimum units capable of displaying white light in the respective pixel areas PX_d may include a plurality of emission areas EA1, EA2, EA3, and EA4. In one or more embodiments of the present disclosure, it has been illustrated that the respective pixels PX include four emission areas EA1, EA2, EA3, and EA4 located in a PENTILE™ matrix structure (e.g., an RGBG matrix structure, a PENTILE™ matrix structure, a PENTILE™ structure, or an RGBG structure, PENTILE™ being a registered trademark of Samsung Display Co., Ltd., Republic of Korea), but the present disclosure is not limited thereto. For example, each of the plurality of pixels PX may include only three emission areas EA1, EA2, and EA3 in one or more other embodiments.

The plurality of emission areas EA1, EA2, EA3, and EA4 for each pixel area PX_d may be partitioned by a partition wall PW. The partition wall PW may be located to surround each of first to fourth light-emitting elements LE1 to LE4 located in the emission areas EA1, EA2, EA3, and EA4. The partition wall PW may be located to be spaced apart from each of the first to fourth light-emitting elements LE1 to LE4. The partition wall PW may have a mesh shape, a net shape, or a lattice shape in plan view.

It is illustrated in FIGS. 8 and 9 that each of the plurality of emission areas EA1, EA2, EA3, and EA4 defined by the partition wall PW has a rhombic shape, in plan view, forming the PENTILE™ matrix structure, but the present disclosure is not limited thereto. For example, each of the plurality of emission areas EA1, EA2, EA3, and EA4 defined by the partition wall PW may have a polygonal shape, such as a quadrangular shape or a triangular shape other than the rhombic shape, a circular circuit, an elliptical shape, or an irregular shape.

Referring to FIG. 9, of the plurality of emission areas EA1, EA2, EA3 and EA4, a first emission area EA1 may include a first light-emitting element LE1 for emitting first light, a second emission area EA2 may include a second light-emitting element LE2 for emitting second light, a third emission area EA3 may include a third light-emitting element LE3 for emitting third light, and a fourth emission area EA4 may include a fourth light-emitting element LE4 for emitting fourth light. The first light may be light of a wavelength band implementing any one of red, green, and blue. In addition, the second light may be light of a wavelength band implementing any one color different from that of the first light among the red, the green, and the blue. Further, the third light may be light of a wavelength band implementing any one color different from those of the first light and the second light among the red, the green, and the blue. In addition, the fourth light may be light of the same wavelength band as any one of the first light to the third light.

It is illustrated that each of the first to fourth light-emitting elements LE1 to LE4 included in the first to fourth emission areas EA1 to EA4 located in the PENTILE™ matrix structure has a rhombic shape in plan view, but the present disclosure is not limited thereto. For example, each of the first to fourth light-emitting elements LE1 to LE4 may be formed in a polygonal shape, such as a triangular shape or a quadrangular shape other than the rhombus shape, a circular shape, an elliptical shape, or an irregular shape.

Each of the first emission areas EA1 refers to an area emitting the first light. Each of the first emission areas EA1 outputs the first light emitted from the first light-emitting element LE1. As described above, the first light may be the light of the wavelength band implementing any one of the red, the green, and the blue. As an example, the first light may be light of a red wavelength band. The red wavelength band may be about 600 nm to about 750 nm, but the present disclosure is not limited thereto.

Each of the second emission areas EA2 refers to an area emitting the second light. Each of the second emission areas EA2 outputs the second light emitted from the second light-emitting element LE2. The second light may be the light of the wavelength band implementing any one color different from that of the first light among the red, the blue, and the green. As an example, the second light may be light of a blue wavelength band. The blue wavelength band may be about 370 nm to about 460 nm, but the present disclosure is not limited thereto.

Each of the third emission areas EA3 refers to an area emitting the third light. Each of the third emission areas EA3 outputs the third light emitted from the third light-emitting element LE3. The third light may be the light of the wavelength band implementing any one color different from those of the first light and the second light among the red, the blue, and the green. As an example, the third light may be light of a green wavelength band. The green wavelength band may be about 480 nm to about 560 nm, but the present disclosure is not limited thereto.

Each of the fourth emission areas EA4 refers to an area emitting the fourth light. Each of the fourth emission areas EA4 outputs the fourth light emitted from the fourth light-emitting element LE4. Here, the fourth light may be light implementing the same color as any one of the first light to the third light. As an example, the fourth light may be light of a blue wavelength band that is the same as the second light, or may be light of a green wavelength band that is the same as the third light, although the present disclosure is not limited thereto.

The second emission areas EA2 of the respective pixels PX may be located alternately with the fourth emission areas EA4 of other adjacent pixels PX along the first direction DR1, which is a transverse (or row) direction. In addition, the first emission areas EA1 and the third emission areas EA3 of the respective pixels PX may be alternately located along the first direction DR1, which is the transverse (or row) direction. Further, the fourth emission areas EA4 of the respective pixels PX may be located alternately with the second emission areas EA2 of other adjacent pixels PX along the first direction DR1, which is the transverse (or row) direction.

The first emission areas EA1 and the fourth emission areas EA4 are alternately located in the fourth direction DR4, which is a first diagonal direction, and the second emission areas EA2 and the third emission areas EA3 are also alternately located in the fourth direction DR4, which is the first diagonal direction. Accordingly, the second emission areas EA2 and the first emission areas EA1 are alternately located in the fifth direction DR5, which is a second diagonal direction crossing the first diagonal direction, and the third emission areas EA3 and the fourth emission areas EA4 are also alternately located in the fifth direction DR5, which is the second diagonal direction, such that the respective pixels PX may also be located and arranged in the PENTILE™ matrix structure as a whole.

Sizes or planar areas of some or all of the first to fourth emission areas EA1 to EA4 of each pixel PX may be the same as or different from each other. Likewise, sizes or planar areas of some or all of the first to fourth light-emitting elements LE1 to LE4 each formed in the first to fourth emission areas EA1 to EA4 may be the same as or different from each other.

For example, an area of the first emission area EA1, an area of the second emission area EA2, an area of the third emission area EA3, and an area of the fourth emission area EA4 may be substantially the same as each other, but the present disclosure is not limited thereto. For example, areas of the first and second emission areas EA1 and EA2 may be different from each other, areas of the second and third emission areas EA2 and EA3 may also be different from each other, and areas of the third and fourth emission areas EA3 and EA4 may also be different from each other. In one or more embodiments, areas of at least two pairs of the first to fourth emission areas EA1 to EA4 may be the same as each other.

A distance between the first and second emission areas EA1 and EA2 neighboring to each other in a horizontal direction or the diagonal direction, a distance between the second and third emission areas EA2 and EA3 neighboring to each other in the horizontal direction or the diagonal direction, a distance between the third and fourth emission areas EA3 and EA4 neighboring to each other in the horizontal direction or the diagonal direction, and a distance between the first and fourth emission areas EA1 and EA4 neighboring to each other in the horizontal direction or the diagonal direction may be the same as each other, but may also be different from each other according to different areas, although the present disclosure is not limited thereto.

The present disclosure is not limited to an example in which the first emission area EA1 emits the first light, the second emission area EA2 emits the second light, the third emission area EA3 emits the third light, and the fourth emission area EA4 emits the same light as any one of the first light to the third light. At least one of the first to fourth emission areas EA1 to EA4 may also emit fifth light. Here, the fifth light may be light of a yellow wavelength band. That is, a main peak wavelength of the fifth light may be positioned at about 550 nm to about 600 nm, but the present disclosure is not limited thereto.

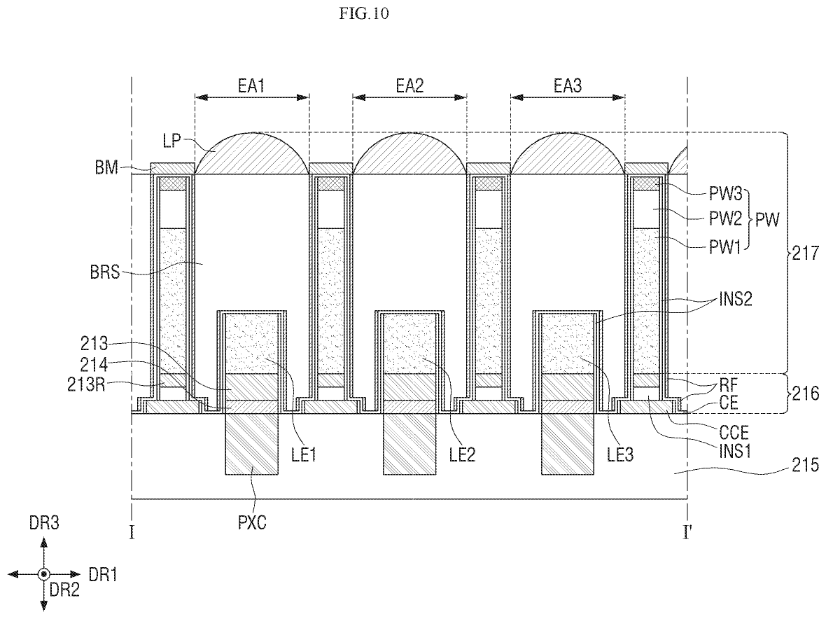

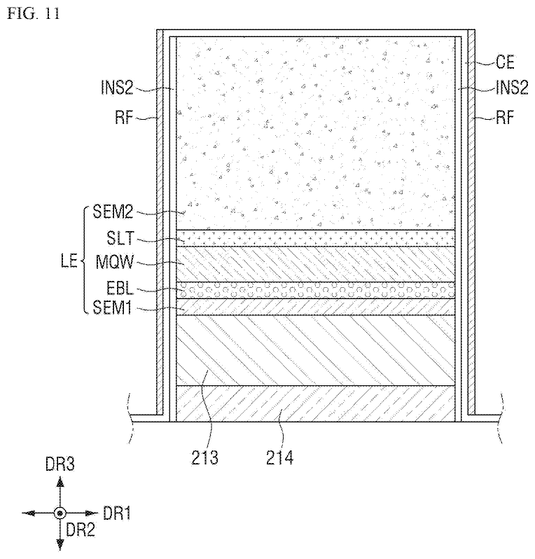

FIG. 10 is a cross-sectional view illustrating an example of the main display panel taken along the line I-I′ of FIG. 9. In addition, FIG. 11 is an enlarged cross-sectional view illustrating an example of a light-emitting element of FIG. 10 in detail.

Referring to FIGS. 10 and 11, the main display panel DPD may include a semiconductor circuit substrate 215, a conductive connection layer 216, and a light-emitting element layer 217.

The semiconductor circuit substrate 215 may include a plurality of pixel circuit parts PXC and pixel electrodes 214. The conductive connection layer 216 may include connection electrodes 213, first pads PD1, a common connection electrode CCE, a first insulating layer INS1, and a conductive pattern 213R.

The semiconductor circuit substrate 215 may be a silicon wafer substrate formed using a semiconductor process. The plurality of pixel circuit parts PXC of the semiconductor circuit substrate 215 may be formed using a semiconductor process.

The plurality of pixel circuit parts PXC may be located in the display area DA (see FIG. 8). Each of the plurality of pixel circuit parts PXC may be connected to the pixel electrode 214 corresponding thereto. That is, the plurality of pixel circuit parts PXC and a plurality of pixel electrodes 214 may be connected to each other so as to correspond to each other in a one-to-one manner. Each of the plurality of pixel circuit parts PXC may overlap one of the corresponding light-emitting elements LE1 to LE3 in the third direction DR3. Various other modified circuit structures, such as a 3T1C structure, a 2T1C structure, a 7T1C structure, and a 6T1C structure may be applied to each of the pixel circuit parts PXC.

Each of the pixel electrodes 214 may be located on the pixel circuit part PXC corresponding thereto. Each of the pixel electrodes 214 may be an exposed electrode exposed from the pixel circuit part PXC. That is, each of the pixel electrodes 214 may protrude from an upper surface of the pixel circuit part PXC. Each of the pixel electrodes 214 may be formed integrally with the pixel circuit part PXC. Each of the pixel electrodes 214 may receive a pixel voltage or an anode voltage supplied from the pixel circuit part PXC. The pixel electrodes 214 may be made of aluminum (Al).

Each of the connection electrodes 213 may be located on the pixel electrode 214 corresponding thereto. Each of the connection electrodes 213 may be located on the pixel electrode 214. The connection electrodes 213 may include a metal material for adhering the pixel electrodes 214 to the respective light-emitting elements LE1 to LE3.

The common connection electrode CCE may be located to be spaced apart from the pixel electrodes 214 and the connection electrodes 213. The common connection electrode CCE may be located to surround the pixel electrodes 214 and the connection electrodes 213. The common connection electrode CCE may be connected to any one of the first pads PD1 of the first pad part PDA1 of the non-display area NDA to receive a common voltage. The common connection electrode CCE may include the same material as the connection electrodes 213.

The first insulating layer INS1 may be located on the common connection electrode CCE. A width of the first insulating layer INS1 in the first direction DR1 or the second direction DR2 may be smaller than a width of the common connection electrode CCE. Accordingly, a portion of an upper surface of the common connection electrode CCE is not covered by the first insulating layer INS1, and may be exposed. A portion of the upper surface of the common connection electrode CCE that is not covered by the first insulating layer INS1 and is exposed may be in contact with a common electrode CE. Therefore, the common electrode CE may be connected to the common connection electrode CCE.

The conductive pattern 213R may be located on the first insulating layer INS1. The conductive pattern 213R may be located between the first insulating layer INS1 and the partition wall PW. A width of the conductive pattern 213R may be substantially the same as the width of the first insulating layer INS1 or a width of the partition wall PW. The conductive pattern 213R corresponds to a residue formed by the same process as a process of forming the connection electrodes 213 and the common connection electrode CCE.

The light-emitting element layer 217 may include the respective light-emitting elements LE1, LE2, LE3, and LE4, the partition wall PW, a second insulating layer INS2, the common electrode CE, a reflective layer RF, a light blocking member BM, and optical patterns LP.

The light-emitting element layer 217 may include the first to fourth emission areas EA1 to EA4 partitioned by the partition wall PW. At least one of the light-emitting element LE and the optical pattern LP may be located in each of the first to fourth emission areas EA1 to EA4.

The light-emitting elements LE1, LE2, and LE3 of FIG. 10 may be located on the connection electrodes 213 in the emission areas EA1 to EA3, respectively. A length (or a height) of each of the light-emitting elements LE1, LE2, and LE3 in the third direction DR3 may be greater than a length thereof in the horizontal direction. The length in the horizontal direction refers to a length in the first direction DR1 or a length in the second direction DR2. For example, a length of the first light-emitting element LE1 in the third direction DR3 may be about 1 μm to about 5 μm.

Referring to FIG. 11, the light-emitting element LE includes a first semiconductor layer SEM1, an electron blocking layer EBL, an active layer MQW, a superlattice layer SLT, and a second semiconductor layer SEM2. The first semiconductor layer SEM1, the electron blocking layer EBL, the active layer MQW, the superlattice layer SLT, and the second semiconductor layer SEM2 may be sequentially stacked in the third direction DR3.

The first semiconductor layer SEM1 may be located on the connection electrode 213. The first semiconductor layer SEM1 may be a semiconductor layer doped with a first conductivity-type dopant, such as Mg, Zn, Ca, Sr, or Ba. For example, the first semiconductor layer SEM1 may be made of p-GaN doped with p-type Mg. A thickness of the first semiconductor layer SEM1 may be about 30 nm to about 200 nm.

The electron blocking layer EBL may be located on the first semiconductor layer SEM1. The electron blocking layer EBL may be a layer for suppressing or preventing too many electrons from flowing into the active layer MQW. For example, the electron blocking layer EBL may be made of p-AlGaN doped with p-type Mg. A thickness of the electron blocking layer EBL may be about 10 nm to about 50 nm. The electron blocking layer EBL may be omitted.

The active layer MQW may be divided into first to third active layers. Each of the first to third active layers may include a material having a single or multiple quantum well structure. When each of the first to third active layers includes the material having the multiple quantum well structure, each of the first to third active layers may have a structure in which a plurality of well layers and barrier layers are alternately stacked. In this case, the first active layer may include InGaN or GaAs, and the second active layer and the third active layer may include InGaN, but the present disclosure is not limited thereto. Here, the first active layer may emit light by a combination of electron-hole pairs according to an electrical signal. The first active layer may emit first light having a main peak wavelength in the range of about 600 nm to about 750 nm, that is, light of a red wavelength band. The second active layer may emit light by a combination of electron-hole pairs according to an electrical signal. The second active layer may emit third light having a main peak wavelength in the range of about 480 nm to about 560 nm, that is, light of a green wavelength band. The third active layer may emit light by a combination of electron-hole pairs according to an electrical signal. The third active layer may emit second light having a main peak wavelength in the range of about 370 nm to about 460 nm, that is, light of a blue wavelength band.

A color of the light emitted from each of the first to third active layers may be changed according to a content of indium in each of the first to third active layers. For example, as the content of indium decreases, a wavelength band of the light emitted from each of the first to third active layers may move to a red wavelength band, and as the content of indium decreases, a wavelength band of the light emitted from each of the first to third active layers may move to a blue wavelength band. The content of indium (In) in the first active layer may be higher than that of indium (In) in the second active layer, and the content of indium (In) in the second active layer may be higher than that of indium (In) in the third active layer. For example, the content of indium (In) in the third active layer may be about 15%, the content of indium (In) in the second active layer may be about 25%, and the content of indium (In) in the first active layer may be about 35% or higher.

Because the color of emitted light may be changed according to the content of indium in each of the first to third active layers, the light-emitting element layers 217 of the respective light-emitting elements LE1, LE2, and LE3 may emit light, such as the first light, the second light, and the third light that are the same as or different from each other according to the content of indium. For example, when the contents of indium (In) in the first to third active layers of the first light-emitting element LE1 are about 35% or higher, the first light-emitting element LE1 may emit the first light of the red wavelength band having the main peak wavelength in the range of about 600 nm to about 750 nm. In addition, when the contents of indium (In) in the third active layers of the second light-emitting element LE2 are about 15%, the second light-emitting element LE2 may emit the second light of the blue wavelength band having the main peak wavelength in the range of about 370 nm to about 460 nm. In addition, when the contents of indium (In) in the second active layer of the third light-emitting element LE3 are about 25%, the third light-emitting element LE3 may emit the third light of the green wavelength band having the main peak wavelength in the range of about 480 nm to about 560 nm. By adjusting and setting the contents of indium (In) in the active layer of the fourth light-emitting element LE4, the fourth light-emitting element LE4 may also emit the first to third lights or may emit another fourth light.

The superlattice layer SLT may be located on the active layer MQW. The superlattice layer SLT may be a layer for alleviating stress between the second semiconductor layer SEM2 and the active layer MQW. For example, the superlattice layer SLT may be made of InGaN or GaN. A thickness of the superlattice layer SLT may be about 50 nm to about 200 nm. The superlattice layer SLT may be omitted.

The second semiconductor layer SEM2 may be located on the superlattice layer SLT. The second semiconductor layer SEM2 may be doped with a second conductivity-type dopant, such as Si, Se, Ge, or Sn. For example, the second semiconductor layer SEM2 may be made of n-GaN doped with n-type Si. A thickness of the second semiconductor layer SEM2 may be about 2 μm to about 4 μm.

Referring to FIG. 10, the partition wall PW may be located to be spaced apart from each of the light-emitting elements LE1 to LE4 located in each of the first to fourth emission areas EA1 to EA4. The partition wall PW may be located to surround the light-emitting elements LE1 to LE4 each located in the first to fourth emission areas EA1 to EA4.

The partition wall PW may be located on the common connection electrode CCE. A width of the partition wall PW in the first direction DR1 and the second direction DR2 may be smaller than the width of the common connection electrode CCE. The partition wall PW may be located to be spaced apart from the light-emitting elements LE.

The partition wall PW may include a first partition wall PW1, a second partition wall PW2, and a third partition wall PW3. The first partition wall PW1 may be located on the first insulating layer INS1. The first partition wall PW1 is formed by the same process as a process of the light-emitting element LE, and thus, at least a portion of the first partition wall PW1 may include the same material as the light-emitting element LE.

The second insulating layer INS2 may be located on side surfaces of the common connection electrode CCE, side surfaces of the partition wall PW, side surfaces of each of the pixel electrodes 214, side surfaces of each of the connection electrodes 213, and side surfaces of each of the light-emitting elements LE1 to LE4. The second insulating layer INS2 may be formed as an inorganic film, such as a silicon oxide layer (SiO₂). A thickness of the second insulating layer INS2 may be about 0.1 μm.

The common electrode CE may be located on an upper surface and the side surfaces of each of the light-emitting elements LE1 to LE4 and an upper surface and the side surfaces of the partition wall PW. That is, the common electrode CE may be located to cover the upper surface and the side surfaces of each of the light-emitting elements LE1 to LE4 and the upper surface and the side surfaces of the partition wall PW.

The common electrode CE may be in contact with the second insulating layer INS2 located on the side surfaces of the common connection electrode CCE, the side surfaces of the partition wall PW, the side surfaces of each of the pixel electrodes 214, the side surfaces of each of the connection electrodes 213, and the side surfaces of each of the light-emitting elements LE1 to LE4. In addition, the common electrode CE may be in contact with the upper surface of the common connection electrode CCE, the upper surface of each of the light-emitting elements LE1 to LE4, and the upper surface of the partition wall PW.

The common electrode CE may be in contact with the upper surface of the common connection electrode CCE and the upper surfaces of the light-emitting elements LE1 to LE4 that are not covered by the second insulating layer INS2 and are exposed. Therefore, the common voltage supplied to the common connection electrode CCE may be applied to the light-emitting elements LE1 to LE4. That is, one ends of the light-emitting elements LE1 to LE4 may receive the pixel voltage or the anode voltage of the pixel electrodes 214 through the connection electrodes 213, and the other ends of the light-emitting elements LE1 to LE4 may receive the common voltage through the common electrode CE. The light-emitting element LE may emit light with a luminance (e.g., predetermined luminance) according to a voltage difference between the pixel voltage and the common voltage.

The reflective layer RF may be located on the side surfaces of the common connection electrode CCE, the side surfaces of the partition wall PW, the side surfaces of each of the pixel electrodes 214, the side surfaces of each of the connection electrodes 213, and the side surfaces of each of the light-emitting elements LE1 to LE4. The reflective layer RF serves to reflect light traveling toward left and right side surfaces rather than an upward direction, in the light emitted from the light-emitting elements LE1 to LE4. The reflective layer RF may include a metal material having high reflectivity, such as aluminum (Al). A thickness of the reflective layer RF may be about 0.1 μm.

A base resin BRS may be located on a passivation layer in each of the light-emitting elements LE1 to LE4. The base resin BRS may include a light-transmitting organic material. The base resin BRS may further include scatterers for scattering the light of the light-emitting elements LE1 to LE4 in a random direction. In this case, the scatterers may include metal oxide particles or organic particles.

The light blocking member BM may be located on the partition wall PW. The light blocking member BM may include a light blocking material. The light blocking member BM may be located between the respective emission areas EA1, EA2, EA3 and EA4 adjacent to each other to prevent color mixing of lights of different wavelength bands emitted from the light-emitting elements LE1 to LE4 of the respective emission areas EA1, EA2, EA3, and EA4. In addition, the light blocking member BM may reduce external light reflection by absorbing at least a portion of external light incident from the outside onto the light-emitting element layer 217. The light blocking member BM may be positioned on the partition wall PW, and may be located to further extend to the respective emission areas EA1, EA2, EA3, and EA4. That is, a width of the light blocking member BM may be greater than the width of the partition wall PW.

Each of the optical patterns LP may be selectively located on each of the emission areas EA1, EA2, EA3, and EA4. Each of the optical patterns LP may be directly located on the base resin BRS of each of the emission areas EA1, EA2, EA3, and EA4. The optical patterns LP may have a shape in which they protrude in an upward direction (e.g., a direction from the light-emitting elements LE1 to LE4 toward the respective optical patterns LP). For example, a cross section of each of the optical patterns LP may have an upwardly convex lens shape. Each of the optical patterns LP may be located on the base resin BRS and the light blocking member BM located therebelow. A width of each optical pattern LP may be equal to, greater than, or smaller than a width of each of the emission areas EA1, EA2, EA3, and EA4. The respective optical patterns LP may collect the first light to the third light or the fourth light transmitted through the base resin BRS in the respective emission areas EA1, EA2, EA3, and EA4.

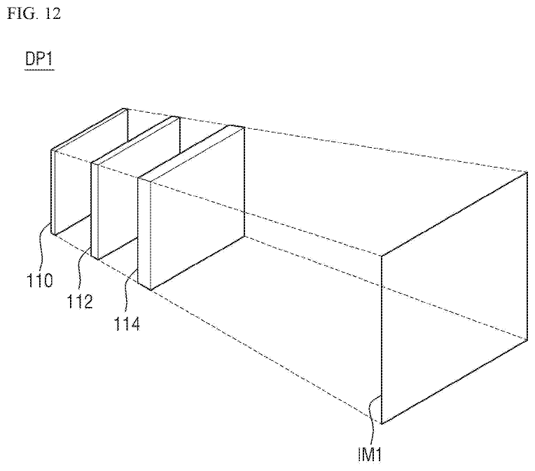

FIG. 12 is a schematic view illustrating a configuration of any one display module illustrated in FIG. 4.

Referring to FIG. 12, the first to sixth display modules DP1 to DP6 allow a first driving environment image IM1 including driving information and distance information between mobile means to be externally displayed on windscreens or windows, external surfaces, and the like of the mobile means, so as to be shown to other mobile means, such as other surrounding vehicles. All of detailed structures and components of each of the first to sixth display modules DP1 to DP6 and detailed structures and components of the screen display module DPU may be configured to be the same as each other. Accordingly, structural features of the first display module DP1 will be described as an example.

The first display module DP1 may include at least one micro display panel 110, at least one diffusion lens 112, and at least one focus forming lens 114. In addition, the first display module DP1 may further include optical members, such as a refractive lens and an optical waveguide capable of changing a display path (or an optical path) of the first driving environment image IM1. The first driving environment image IM1 displayed through each micro display panel 110 may be emitted in a front direction through at least one diffusion lens 112, at least one focus forming lens 114, the optical members, and the like. The micro display panel 110 has a structure and components substantially same as those of the main display panel DPD shown in FIG. 10.

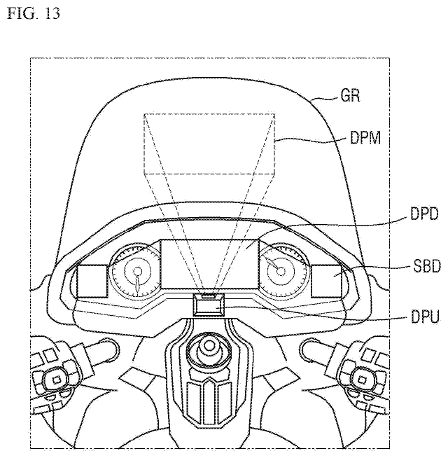

FIG. 13 is a view illustrating an image display method of the main display panel, the sub-display panel, and the screen display module according to one or more embodiments.

Referring to FIG. 13, the screen display module DPU may be located in the front direction of the driver's seat, such as the top cowling cover, separately from the main display panel DPD. The screen display module DPU emits an image so that a screen driving image DPM is displayed through a windscreen GR of the mobile means under the control of the main processor MCU.

For example, the screen driving image DPM displayed on the micro display panel 110 of the screen display module DPU may be emitted toward the wind screen GR through at least one diffusion lens 112 and at least one focusing forming lens 114.

The micro display panel 110 of the screen display module DPU may emit at least one of at least one image captured by each of the camera modules CM1 to CM6, the surrounding-environment-information image, the driving-environment-information image, the instrument-information image, the driving-information image, and the safety-state-information image to at least one diffusion lens 112 and at least one focus forming lens 114. Accordingly, at least one image displayed through the screen display module DPU may be recognized by the driver's eyes through the windscreen in the front direction.

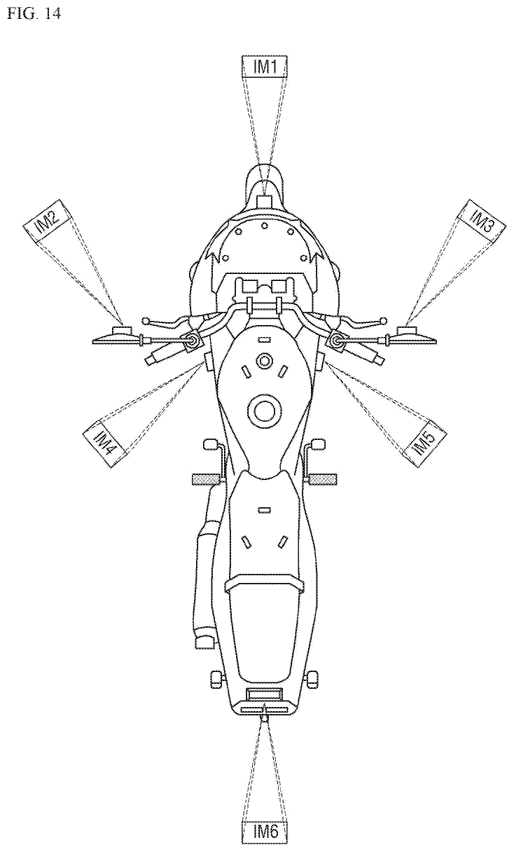

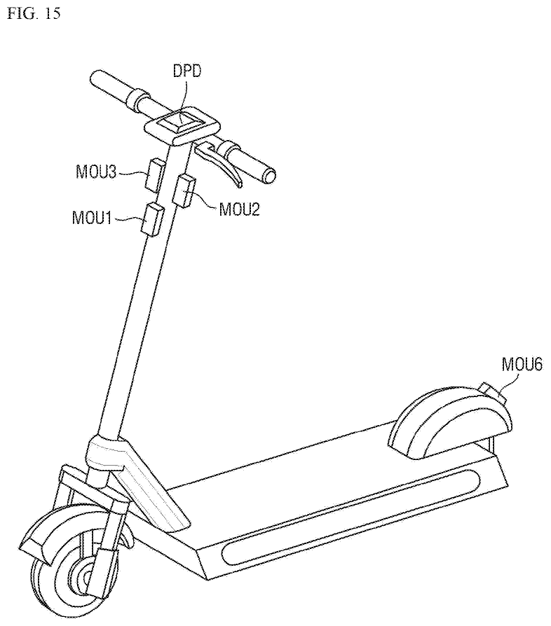

FIG. 14 is an illustrative view illustrating image emission directions of first to sixth display modules illustrated in FIGS. 1 to 4.

Referring to FIG. 14, the first to sixth display modules DP1 to DP6 of the display device may be located at the same positions as the first to sixth camera modules CM1 to CM6 and in the same directions as the first to sixth camera modules CM1 to CM6 in parallel with the first to sixth camera modules CM1 to CM6, respectively. Accordingly, the first to sixth display modules DP1 to DP6 may emit first to sixth driving environment images IM1 to IM6 in the same directions as the image capturing directions of the first to sixth camera modules CM1 to CM6, respectively. The first to sixth driving environment images IM1 to IM6 may include driving information or position-information images, respectively.

For example, the first to sixth display modules DP1 to DP6 may be located respectively in at least one of the front direction, the rear direction, the side direction, and the diagonal direction on the surfaces of one or more rearview mirrors formed in the mobile means, similar to the first to sixth camera modules CM1 to CM6. Accordingly, the first to sixth display modules DP1 to DP6 may be located in the respective different directions on the basis of the mobile means. In addition, the first to sixth display modules DP1 to DP6 may emit the first to sixth driving environment images IM1 to IM6 in at least one of the front direction, the rear direction, the side direction, and the diagonal direction on the surfaces of one or more rearview mirrors, respectively.

Alternatively, the first to sixth display modules DP1 to DP6 may be located respectively in different directions on at least one of the top cowling cover, the bottom cowling cover, the front or side grille, the front and side covers, and the taillight cover, as well as on one or more rearview mirrors of the mobile means, similar to the first to sixth camera modules CM1 to CM6.

For example, the first display module DP1 of the first to sixth display modules DP1 to DP6 may be located in the front direction of the mobile means on the rearview mirror or the front cover of the mobile means, and may emit the first driving environment image IM1 in the front direction of the mobile means. In addition, the second display module DP2 may be located in one side direction of the mobile means on one rearview mirror or the top cowling cover of the mobile means, and may emit the second driving environment image IM2 in one side direction or one side diagonal direction of the mobile means.

In addition, the third display module DP3 of the first to sixth display modules DP1 to DP6 may be located in the other side direction of the mobile means on the other rearview mirror or the top cowling cover of the mobile means, and may emit the third driving environment image IM3 in the other side direction or the other side diagonal direction of the mobile means. The fourth display module DP4 may be located in one side diagonal direction of the mobile means on or adjacent to the one rearview mirror or one side cover of the mobile means, and may emit the fourth driving environment image IM4 in one side diagonal direction of the mobile means.

The fifth display module DP5 may be located in the other side diagonal direction of the mobile means on or adjacent to the other rearview mirror or the other side cover of the mobile means, and may emit the fifth driving environment image IM5 in the other side diagonal direction of the mobile means. In addition, the sixth display module DP6 may be located in the rear direction of the mobile means on the rearview mirror or the taillight cover of the mobile means, and may emit the sixth driving environment image IM6 in the rear direction of the mobile means.

Accordingly, the display device and the two-wheeled mobile device using the same according to one or more embodiments of the present disclosure display the driving information and the safety state information of the mobile means in real time in conjunction with various electronic devices, such as cameras and sensors, such that the usability of the display devices may be increased. In addition, the display device and the two-wheeled mobile device using the same according to one or more embodiments of the present disclosure display various information images on the instrument board, the windscreen, and the like, using the micro LED display device, and thus, may further improve a display quality of an information display image.

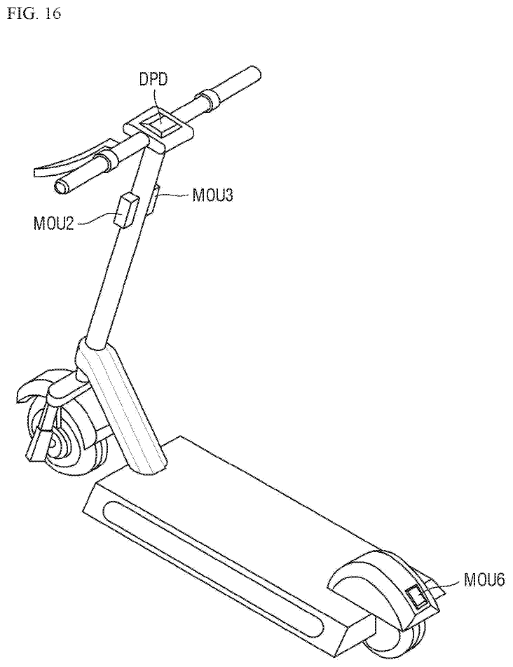

FIG. 15 is a perspective view illustrating an example in which the display device of the present disclosure is applied to a personal mobile device according to one or more other embodiments. In addition, FIG. 16 is another perspective view illustrating an example in which the display device of the present disclosure is applied to another personal mobile device.

Referring to FIGS. 15 and 16, the display device according to the present disclosure may be mounted in, or formed integrally with, a personal mobile device, such as an electric scooter, an electric bicycle, or a two-wheeled parallel vehicle.

For example, the display device may display surrounding environment information, driving environment information, instrument information, driving information, safety state information, and the like, of the personal mobile device on an instrument board in conjunction with electric devices, such as a sensing module, a camera module, and a main board of the personal mobile device.

For example, a plurality of multiprocessors of the multiprocessors MOU1 to MOU6 of the display device may be located in different directions on the basis of the personal mobile device, may capture images in different directions, and may sense distances to proximate objects. In addition, the respective multiprocessors may display images from the main processor on the main display panel DPD under the control of the main processor.

The plurality of multiprocessors MOU1 to MOU6 may be located respectively in different directions on at least one of a front cover, a side cover, and a taillight cover of the personal mobile device. Accordingly, the respective multiprocessors MOU1 to MOU6 may capture images in at least one of a front direction, a side direction, a rear direction, and a diagonal direction of the personal mobile device and may sense distances to proximate objects. The respective multiprocessors MOU1 to MOU6 may display a driving information or position-information image on the main display panel DPD under the control of the main processor.

The main display panel DPD or the micro display panels 110 included in the display device according to the present disclosure may be applied to smartphones, tablet mobile communication devices, such as tablet personal computers (PCs), personal digital assistants (PDAs), portable multimedia players (PMPs), televisions, game machines, monitors of PCs, laptop computers, flat-panel image display devices, vehicle navigation devices, vehicle instrument boards, digital cameras, camcorders, and the like.

In addition, the main display panel DPD or the micro display panels 110 included in the display device according to the present disclosure may be applied to wrist watch-type electronic devices, head-mounted displays, external billboards, electric signs, medical devices, inspection devices, various home appliances, such as refrigerators and washing machines, Internet of Things (IoT) devices, and the like.

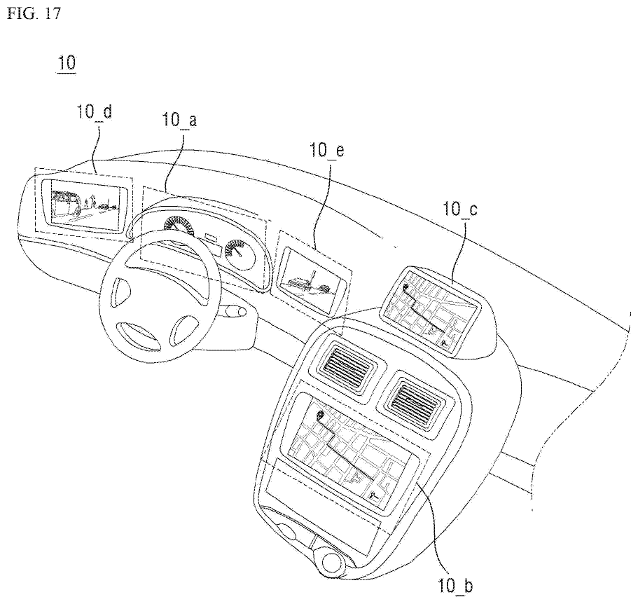

FIG. 17 is an illustrative view illustrating an instrument board and a center fascia of a vehicle including a display module according to one or more embodiments.

Referring to FIG. 17, the main display panel DPD or the micro display panels 110 included in the display device according to the present disclosure may be applied to a display device 10 of a dashboard of a vehicle. As an example, the main display panel DPD or the micro display panels 110 may be applied to an instrument board 10_a of the vehicle, may be applied to a center fascia 10_b of the vehicle, or may be applied to a center information display (CID) 10_c located on the dashboard of the vehicle. In addition, the main display panel DPD or the micro display panels 110 according to one or more embodiments may be applied to room mirror displays 10_d and 10_e substituting for side mirrors of the vehicle, a navigation device, and the like.

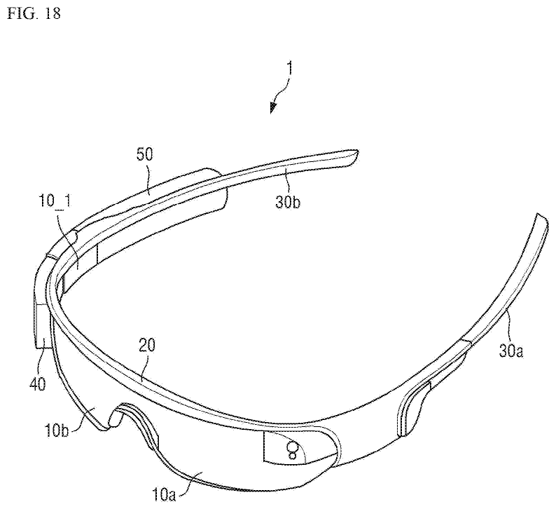

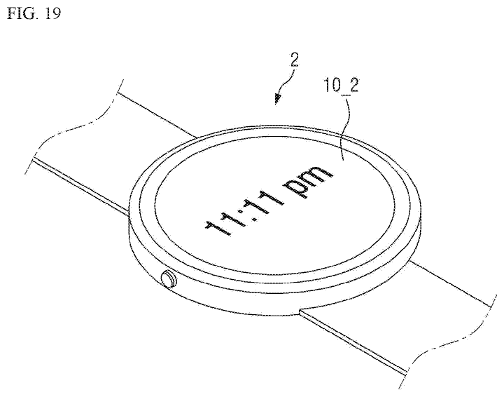

FIG. 18 is an illustrative view illustrating an eyeglasses-type virtual reality device including the display module according to one or more embodiments. In addition, FIG. 19 is an illustrative view illustrating a watch-type smart device including the display module according to one or more embodiments.

FIG. 18 illustrates an eyeglasses-type virtual reality device 1 including eyeglasses frame legs 30a and 30b. The eyeglasses-type virtual reality device 1 according to one or more embodiments may include a virtual image display device 10-1, a left eye lens 10a, a right eye lens 10b, a support frame 20, eyeglasses frame legs 30a and 30b, a reflective member 40, and a display device accommodating part 50. The virtual image display device 10_1 may display a virtual image using the main display panel DPD or the micro display panels 110 illustrated as one or more embodiments of the present disclosure.

The eyeglasses-type virtual reality device 1 according to one or more embodiments may also be applied to a head mounted display including a head mounted band that may be mounted on a user's head instead of the eyeglasses frame legs 30a and 30b. That is, the eyeglasses-type virtual reality device 1 according to one or more embodiments is not limited to that illustrated in FIG. 18, and may be applied in various forms to various other electronic devices.

In addition, as illustrated in FIG. 19, the main display panel DPD or the micro display panels 110 illustrated as one or more embodiments of the present disclosure may be applied to a display device 10_2 of a watch-type smart device 2, which is one of smart devices.

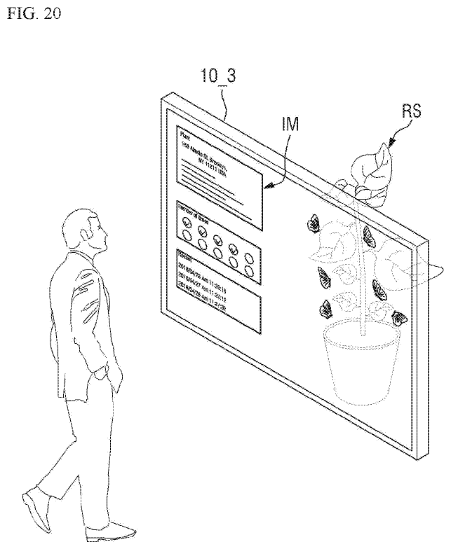

FIG. 20 is an illustrative view illustrating a transparent display device including the display module according to one or more embodiments.

Referring to FIG. 20, the main display panel DPD or the micro display panels 110 included in the display device according to the present disclosure may be applied to the transparent display device 10_3. The transparent display device 10_3 may transmit light while displaying an image IM. Therefore, a user positioned on a front surface of the transparent display device 10_3 may not only view the image IM displayed on the micro display panel 110, but also see an object RS or a background positioned on a rear surface of the transparent display device 10_3. When the micro display panel 110 is applied to the transparent display device 10_3, the micro display panel 110 illustrated in FIG. 12 may include a light transmitting part capable of transmitting light or may be made of a material capable of transmitting light.

In concluding the detailed description, those skilled in the art will appreciate that many variations and modifications can be made to the embodiments without substantially departing from the aspects of the present disclosure. Therefore, the disclosed embodiments of the disclosure are used in a generic and descriptive sense only and not for purposes of limitation.

What is claimed is:

1. A display device comprising:
multiprocessors respectively at different locations in a mobile means, configured to capture images in different directions, and configured to sense distances to proximate objects;
a main display panel on an instrument board of the mobile means, and configured to display at least one of image comprising an image captured by the multiprocessors, a surrounding-environment-information image, a driving-environment-information image, an instrument-information image, a driving-information image, or a safety-state-information image; and
a main processor configured to control an image display operation of the main display panel so that the at least one image is displayed on the main display panel.

2. The display device of claim 1, further comprising:
at least one sub-display panel for displaying at least one second image that is different from the at least one image displayed on the main display panel; and
at least one screen display module for emitting at least one of the image captured by the multiprocessors, the surrounding-environment-information image, the driving-environment-information image, the instrument-information image, the driving-information image, and the safety-state-information image to a windscreen, to a mirror, or to a surface of any one cover of the mobile means.

3. The display device of claim 2, wherein the main processor is configured to control an image display operation of each of the at least one sub-display panel and the at least one screen display module so that the at least one image is displayed on the at least one sub-display panel and the at least one screen display module.

4. The display device of claim 2, wherein at least one of the main display panel and the sub-display panel comprises:
a partition wall partitioned and in an RGBG matrix structure on a substrate;
light-emitting elements respectively in emission areas arranged in the RGBG matrix structure by partition of the partition wall, and extending in a thickness direction of the substrate;
base resins in the emission areas comprising the light-emitting elements; and
optical patterns selectively on at least one of the emission areas.

5. The display device of claim 4, wherein first to third emission areas or first to fourth emission areas of the emission areas are in the RGBG matrix structure in each pixel area,
wherein the first emission area comprises a first light-emitting element for emitting first light of a wavelength band implementing any one of red, green, and blue,
wherein the second emission area comprises a second light-emitting element for emitting second light of a wavelength band implementing any one color that is different from that of the first light among red, green, and blue,
wherein the third emission area comprises a third light-emitting element for emitting third light of a wavelength band implementing any one color that is different from those of the first light and the second light among red, green, and blue, and
wherein the fourth emission area comprises a fourth light-emitting element for emitting fourth light of the same wavelength band as any one of the first light to the third light.

6. The display device of claim 5, wherein sizes or planar areas of the first to fourth emission areas are the same as each other, and
wherein a distance between the first and second emission areas neighboring to each other in a horizontal direction or a diagonal direction, a distance between the second and third emission areas neighboring to each other in the horizontal direction or the diagonal direction, a distance between the first and third emission areas neighboring to each other in the horizontal direction or the diagonal direction, and a distance between the third and fourth emission areas neighboring to each other in the horizontal direction or the diagonal direction, are the same as each other.

7. The display device of claim 1, wherein the multiprocessors are respectively at different locations of the mobile means, configured to capture the images in different respective directions, configured to sense respective distances to a proximate object in the different respective directions, and configured to display and emit images from the main processor under the control of the main processor.

8. The display device of claim 7, wherein the multiprocessors are respectively in any one of a front direction, a rear direction, a side direction, and a diagonal direction with respect to the mobile means.

9. The display device of claim 8, wherein first to third multiprocessors of the multiprocessors are on surfaces of a left rearview mirror in the front direction, the side direction, and the rear direction, respectively, configured to capture images in at least one of a front left direction, a left side direction, the rear direction, and a left diagonal direction of the mobile means, and configured to sense distances to a proximate object, and
wherein fourth to sixth multiprocessors of the multiprocessors are on surfaces of a right rearview mirror in the front direction, the side direction, and the rear direction, respectively, configured to capture images in at least one of a front right direction, a right side direction, the rear direction, and a right diagonal direction of the mobile means, and configured to sense distances to the proximate object.

10. The display device of claim 7, wherein the multiprocessors are at different respective locations of at least one of a top cowling cover, a bottom cowling cover, a front grille, a side grille, a front cover, a side cover, a taillight cover, and one or more rearview mirrors of the mobile means.

11. The display device of claim 10, wherein a first multiprocessor of the multiprocessors is in a front direction of the mobile means on a first rearview mirror of the one or more rearview mirrors or the front cover of the mobile means,
wherein a second multiprocessor is in one side direction of the mobile means on a second rearview mirror of the one or more rearview mirrors or the top cowling cover of the mobile means,
wherein a third multiprocessor is in the other side direction of the mobile means on a third rearview mirror of the one or more rearview mirrors or the top cowling cover of the mobile means,
wherein a fourth multiprocessor is in one side diagonal direction of the mobile means on a fourth rearview mirror of the one or more rearview mirrors or one side cover of the mobile means,
wherein a fifth multiprocessor is in the other side diagonal direction of the mobile means on a fifth rearview mirror of the one or more rearview mirrors or the other side cover of the mobile means, and
wherein a sixth multiprocessor is in a rear direction of the mobile means on a sixth rearview mirror of the one or more rearview mirrors or a taillight direction cover of the mobile means.

12. The display device of claim 7, wherein first to sixth multiprocessors of the multiprocessors are at six respective locations of the mobile means, configured to capture images in six respective surface directions, configured to sense distances to proximate objects in the six respective surface directions, and configured display images from the main processor in six respective surface directions under the control of the main processor.

13. The display device of claim 12, wherein the first multiprocessor comprises a first camera module, a first sensing module, and a first display module,
wherein the second multiprocessor comprises a second camera module, a second sensing module, and a second display module,
wherein the third multiprocessor comprises a third camera module, a third sensing module, and a third display module,
wherein the fourth multiprocessor comprises a fourth camera module, a fourth sensing module, and a fourth display module,
wherein the fifth multiprocessor comprises a fifth camera module, a fifth sensing module, and a fifth display module, and
wherein the sixth multiprocessor comprises a sixth camera module, a sixth sensing module, and a sixth display module.

14. The display device of claim 13, wherein the first to sixth display modules comprise a display panel, at least one diffusion lens, and at least one focus forming lens, and
wherein the display panel comprises:
a partition wall partitioned and in an RGBG matrix structure on a substrate;
light-emitting elements each in emission areas arranged in the RGBG matrix structure by partition of the partition wall, and extending in a thickness direction of the substrate;
base resins in the emission areas comprising the light-emitting elements; and
optical patterns selectively on at least one of the emission areas.

15. The display device of claim 13, wherein the first to third camera modules, the first to third sensing modules, and the first to third display modules are respectively on surfaces of a left rearview mirror in a front direction, a side direction, and a rear direction, and
wherein the fourth to sixth camera modules, the fourth to sixth sensing modules, and the fourth to sixth display modules are respectively on surfaces of a right rearview mirror in the front direction, the side direction, and the rear direction.

16. The display device of claim 15, wherein the first to sixth camera modules, the first to sixth sensing modules, and the first to sixth display modules are respectively in different directions on at least one of a top cowling cover, a bottom cowling cover, a front or side grille, front and side covers, a taillight cover, and one or more rearview mirrors of the mobile means.

17. The display device of claim 13, wherein the first camera module, the first sensing module, and the first display module are in a front direction of the mobile means on a rearview mirror or a front cover of the mobile means,
wherein the second camera module, the second sensing module, and the second display module are in one side direction of the mobile means on the rearview mirror or a top cowling cover of the mobile means,
wherein the third camera module, the third sensing module, and the third display module are in the other side direction of the mobile means on the rearview mirror or the top cowling cover of the mobile means,
wherein the fourth camera module, the fourth sensing module, and the fourth display module are in one side diagonal direction of the mobile means on the rearview mirror or one side cover of the mobile means,
wherein the fifth camera module, the fifth sensing module, and the fifth display module are in the other side diagonal direction of the mobile means on the rearview mirror or the other side cover of the mobile means, and
wherein the sixth camera module, the sixth sensing module, and the sixth display module are in a rear direction of the mobile means on the rearview mirror or a taillight direction cover of the mobile means.

18. An operating-environment-information-providing system of a two-wheeled mobile device, comprising:
a display device assembled to, or formed integrally with, the two-wheeled mobile device, and configured to display a driving-environment-information image, an instrument-information image, and a driving-information image of the two-wheeled mobile device,
wherein the display device comprises:
multiprocessors respectively in different directions in the two-wheeled mobile device for capturing images in the different directions, and for sensing distances to proximate objects;
a main display panel for displaying at least one of at least one image captured by the multiprocessors, a surrounding-environment-information image, and a safety-state-information image; and
a main processor for controlling an image display operation of the main display panel so that the at least one image is displayed on the main display panel.

19. The operating-environment-information-providing system of the two-wheeled mobile device of claim 18, wherein the main processor is configured to control an image display operation of each of at least one sub-display panel and at least one screen display module so that the at least one image is displayed on the at least one sub-display panel and the at least one screen display module.

20. The operating-environment-information-providing system of the two-wheeled mobile device of claim 18, wherein the two-wheeled mobile device comprises an electric bicycle, a personal mobile device, a two-wheeled motor device, a two-wheeled parallel vehicle, a motorcycle, or logistics and construction machinery.
